(19) United States
(12) Patent Application Publication
(10) Pub. No.: US 2025/0123154 A1
(43) Pub. Date: Apr. 17, 2025

(54) TEMPERATURE SENSING DEVICE

(71) Applicant: HYUNDAI MOBIS CO., LTD., Seoul (KR)

(72) Inventor: Dong Hyuk KIM, Seoul (KR)

(73) Assignee: HYUNDAI MOBIS CO., LTD., Seoul (KR)

(21) Appl. No.: 18/885,070

(22) Filed: Sep. 13, 2024

(30) Foreign Application Priority Data
Oct. 17, 2023 (KR) 10-2023-0138835

(51) Int. Cl. G01K 7/22; G01R 19/00

(52) U.S. Cl. CPC G01K 7/22; G01R 19/0038

(57) ABSTRACT

A temperature sensing device and a temperature sensing device for a vehicle are provided. The temperature sensing device includes: a negative temperature coefficient (NTC) thermistor installed on a motor; a pull-up resistor connected to one end of the NTC thermistor, the pull-up resistor having a resistance that varies depending on a temperature inside the motor; a voltage output unit to output a voltage based on a change in resistance of the NTC thermistor according to a change in temperature; and a comparison unit including a comparator for comparing the voltage value output from the voltage output unit with a reference voltage, wherein the comparison unit changes the resistance of the pull-up resistor unit based on an output of the comparator.

### CROSS-REFERENCE TO RELATED APPLICATION(S)

This application claims the benefit under 35 U.S.C. § 119 to Korean Patent Application No. 10-2023-0138835, filed on Oct. 17, 2023, in the Korean Intellectual Property Office, the disclosure of which is incorporated herein by reference in its entirety for all purposes.

### BACKGROUND

### 1. Field

The following disclosure relates to a temperature sensing device, and more particularly, to a temperature sensing device having a simple structure while improving the measurable temperature range and measurement accuracy of the temperature sensing device using an NTC thermistor.

### 2. Description of the Related Art

An eco-friendly vehicle is driven by transmitting DC power generated from a high-voltage battery as AC power to the drive motor through an inverter, which is a power conversion device. In order for the inverter to control the drive motor, it is necessary to measure a voltage input from the high-voltage battery, a three-phase current output to the drive motor, and an absolute position of a rotor of the drive motor in permanent magnet type. In addition, a temperature is measured in real time at each location to detect an abnormality and protect the drive motor and the inverter. The temperature greatly affects the performance of the drive motor. If the drive motor is overheated, a permanent magnet, a stator coil, etc. are deformed, causing a deterioration in performance. Therefore, a temperature sensor is installed inside the drive motor to control the drive motor according to a temperature measured by the sensor. A negative temperature coefficient (NTC) thermistor is mainly used as the temperature sensor, and a temperature sensing circuit is designed to measure a temperature of the drive motor in such a manner that the inverter uses a pull-up resistance in consideration of the characteristics of the NTC thermistor.

The temperature sensing circuit of the NTC thermistor needs to sense a temperature by selecting an appropriate pull-up resistance due to the non-linear characteristics of the NTC thermistor. However, in some cases, it may be difficult to linearly sense each temperature. According to the characteristics of the NTC thermistor used when designing a conventionally typical temperature sensing circuit, a temperature may be sensed non-linearly in a specific section. In this case, it is difficult to accurately measure a temperature, and it is required to solve this problem.

In some cases, it is difficult to implement a circuit that reflects the characteristics of drive motor temperature sensors of various types of vehicles by changing a pull-up resistance. Thus, the circuit may be designed by adding an active element such as a transistor to vary the pull-up resistance. A change in magnitude of the pull-up resistance to a relatively small magnitude at a high temperature improves temperature sensing linearity at the high temperature. In this case, it is necessary to additionally design software logic so that the active element operates by comparing a voltage depending on a temperature of the motor and a reference voltage. In this case, there is a problem that a complicated control method needs to be designed to vary the pull-up resistance.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

An embodiment of the present invention is directed to providing a temperature sensing device that improves sensing accuracy at all temperatures by automatically changing a pull-up resistance without designing software.

In a general aspect of the disclosure, a temperature sensing device, includes: a negative temperature coefficient (NTC) thermistor installed on a motor; a pull-up resistor connected to one end of the NTC thermistor, the pull-up resistor having a resistance that varies depending on a temperature inside the motor; a voltage output unit configured to output a voltage based on a change in resistance of the NTC thermistor according to a change in temperature; and a comparison unit including a comparator for comparing the voltage value output from the voltage output unit with a reference voltage, wherein the comparison unit is configured to change the resistance of the pull-up resistor unit based on an output of the comparator.

The comparison unit may include a first reference voltage output unit for outputting a 1-1st reference voltage or a 1-2nd reference voltage, and a second reference voltage output unit for outputting a second reference voltage, and the comparator may include: a first comparator including a non-inverting terminal connected to an output terminal of the first reference voltage output unit, and a first inverting terminal connected to one end of the NTC thermistor and the output terminal of the voltage output unit to compare the output voltage of the first reference voltage output unit with the output voltage of the voltage output unit; and a second comparator including a non-inverting terminal being connected to an output terminal of the second reference voltage output unit, and a second inverting terminal connected to an output terminal of the first comparator to compare the second reference voltage and the output of the first comparator, and turn on or off a switch included in the pull-up resistor unit according to an output.

In response to the output of the first comparator being lower than a predetermined value based on the comparison result, the first reference voltage output unit may output the 1-1st reference voltage, and in response to the output of the first comparator being higher than the predetermined value based on the comparison result, the first reference voltage output unit may output the 1-2nd reference voltage.

The 1-1st reference voltage may be lower than the 1-2nd reference voltage.

The temperature sensing device may further include a direct current (DC) power source connected to the pull-up resistor unit and the comparison unit.

The comparison unit further include: a first resistor of which one end is connected to the non-inverting terminal of the first comparator, and another end is connected to the DC power source; a second resistor of which one end is connected to the one end of the first resistor, and another end is connected to the inverting terminal of the second comparator; a third resistor of which one end is connected to the one end of the first resistor, and another end is grounded; and a fourth resistor of which one end is connected to the other end of the first resistor, and another end is connected to the other end of the second resistor.

The 1-1st reference voltage may be determined by the following formula:

$${V}_{ref 1 - 1} = \frac{( {R}_{2} ‖ {R}_{3} )}{( {R}_{1} + {R}_{2} ‖ {R}_{3} )} \times {V}_{source}$$

where V_{ref1-1} is the 1-1st reference voltage, V_{source} is an output voltage of the DC power source, R₁ is a resistance value of the first resistor, R₂ is a resistance value of the second resistor, R₃ is a resistance value of the third resistor, and R₂∥R₃=(R₂·R₃)/(R₂+R₃).

The 1-2nd reference voltage may be determined by the following formula:

$${V}_{ref 1 - 2} = \frac{{R}_{3}}{( {R}_{1} ‖ {R}_{2} + {R}_{3} )} \times {V}_{source}$$

where V_{ref1-2} is the 1-2nd reference voltage, V_{source} is an output voltage of the DC power source, R₁ is a resistance value of the first resistor, R₂ is a resistance value of the second resistor, R₃ is a resistance value of the third resistor, and R₁∥R₂=(R₁·R₂)/(R₁+R₂).

The pull-up resistor unit may include: a first pull-up resistor of which one end is connected to the NTC thermistor; a second pull-up resistor connected to the first pull-up resistor in parallel; and a switch connected to the second pull-up resistor in series, with a gate terminal thereof being connected to an output terminal of the second comparator, the gate terminal configured to turn on or off the switch according to an output of the second comparator.

The temperature sensing device may further include a protection resistor of which one end is connected to the other end of the NTC thermistor, and another end is grounded.

In another general aspect of the disclosure, a temperature sensing device for a vehicle, includes: a negative temperature coefficient (NTC) thermistor installed on a motor of the vehicle; a pull-up resistor connected to the NTC thermistor, the pull-up resistor having a resistance that varies depending on a temperature of the motor; a voltage outputter configured to output a voltage based on a change in resistance of the NTC thermistor due to a change of the temperature of the motor; and a controller comprising a comparator for comparing the voltage value output by the voltage outputter with a reference voltage, wherein the controller is configured to change the resistance of the pull-up resistor unit based on the comparison of the voltage value output by the voltage outputter with the reference voltage by the comparator.

The controller may include: a first reference voltage outputter for outputting a 1-1st reference voltage or a 1-2nd reference voltage; and a second reference voltage outputter for outputting a second reference voltage, and the comparator may include: a first comparator including: a non-inverting terminal connected to an output terminal of the first reference voltage outputter; and a first inverting terminal connected to one end of the NTC thermistor and the output terminal of the voltage outputter to compare the output voltage of the first reference voltage outputter with the output voltage of the voltage outputter; and a second comparator including: a non-inverting terminal being connected to an output terminal of the second reference voltage outputter; and a second inverting terminal connected to an output terminal of the first comparator to compare the second reference voltage and the output of the first comparator, and turn on or off a switch included in the pull-up resistor according to an output.

In response to the output of the first comparator being lower than a predetermined value based on the comparison result, the first reference voltage outputter may output the 1-1st reference voltage, and in response to the output of the first comparator being higher than the predetermined value based on the comparison result, the first reference voltage outputter may output the 1-2nd reference voltage.

The 1-1st reference voltage may be lower than the 1-2nd reference voltage.

The temperature sensing device may further include a direct current (DC) power source connected to the pull-up resistor and the controller.

### BRIEF DESCRIPTION OF THE DRAWINGS

FIG. 1 is a circuit diagram of a temperature sensing device according to an embodiment of the present invention.

FIG. 2 is a graph showing a temperature measured by an NTC thermistor and a sensing signal voltage value according to a change in resistance value of a pull-up resistor unit in a temperature sensing device according to an embodiment of the present invention.

FIG. 3 is a graph showing an output value of a voltage output unit, an output value of a first comparator, a signal value applied to a switch, a first reference voltage, and a second reference voltage in the temperature sensing device according to an embodiment of the present invention.

### DETAILED DESCRIPTION

The aforementioned objects, features, and advantages of the present invention will be more apparent from the embodiments to be described below with reference to the accompanying drawings. The following specific structural or functional descriptions are provided merely for the purpose of describing embodiments according to the concept of the present invention, and the embodiments according to the concept of the present invention can be implemented in various forms and should not be construed as being limited to the embodiments set forth herein. Since various modifications may be made to the embodiments according to the concept of the present invention, and the embodiments of the present invention may have various forms, specific embodiments will be illustrated in the drawings and described in detail hereinbelow. However, this is not intended to limit the embodiments according to the concept of the present invention to specific forms disclosed herein, and it should be noted that the specific embodiments described herein cover all modifications, equivalents, or substitutes within the spirit and technical scope of the present invention. Terms “first”, “second”, and/or the like may be used to describe various components but the components are not limited by the above terms. The above terms are only used to distinguish one component from another component. For example, a first component may be referred to as a second component, and similarly, a second component may be referred to as a first component, without departing from the scope according to the concept of the present disclosure. It should be noted that, when one component is referred to as being coupled or connected to another component, the one component may be directly coupled or connected to the other component, or the one component may be coupled or connected to the other component through an intervening component therebetween. On the other hand, when one component is referred to as being directly coupled to or directly connected to another component, there is no intervening component therebetween. Other expressions for describing relationships between components, that is, expressions such as “between”, “immediately between”, “adjacent to”, and “directly adjacent to”, shall be construed similarly. Terms used herein are used only to describe the specific embodiments and are not intended to limit the present invention. Singular expressions include plural expressions unless the context clearly indicates otherwise. It should be noted that terms “include”, “have”, and the like used herein are intended to specify the presence of stated features, numbers, steps, operations, components, parts, or combinations thereof but do not preclude the presence or addition of one or more other features, numbers, steps, operations, components, parts, or combinations thereof. Unless otherwise defined, all terms used herein, including technical or scientific terms, have the same meanings as those generally understood by those skilled in the art to which the present invention pertains. The terms defined in generally used dictionaries and the like should be interpreted as having the same meanings as those in the context of the related art, and should not be interpreted as having ideal or excessively formal meanings unless clearly defined herein. Hereinafter, the present invention will be described in detail by describing preferred embodiments of the present invention with reference to the accompanying drawings. Like reference signs in the drawings indicate like elements.

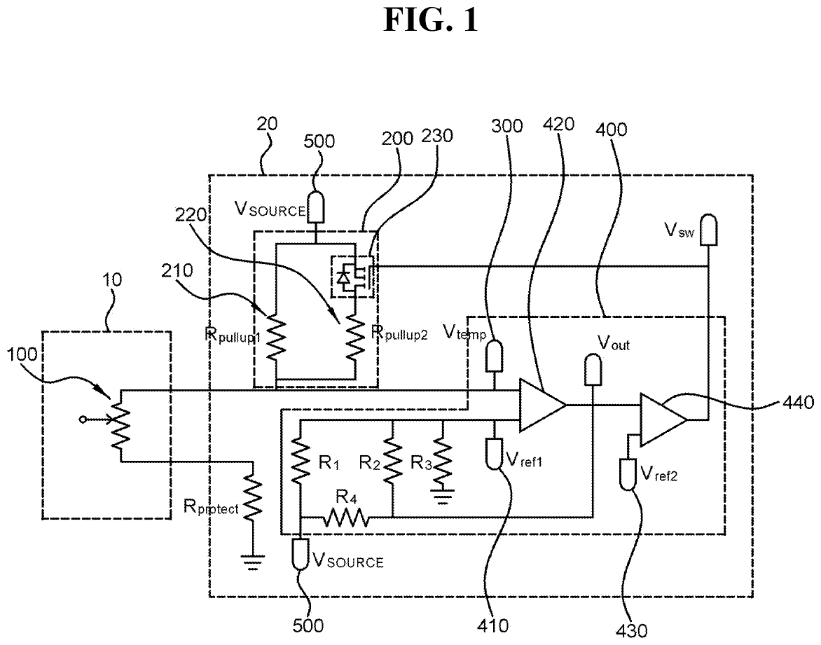

FIG. 1 is a circuit diagram of a temperature sensing device according to an embodiment of the present invention.

As illustrated in FIG. 1, a temperature sensing device according to an embodiment of the present invention includes an NTC thermistor 100, a pull-up resistor unit 200, a DC power source 500, a protection resistor Rprotect, a voltage output unit 300, and a comparison unit 400 (e.g., a controller or a processor).

The NTC thermistor 100 is installed in a motor 10, and includes a resistor having a predetermined resistance value. The resistor of the NTC thermistor 100 has a resistance value that decreases as the temperature rises, and increases as the temperature falls, according to the characteristics of the device. The NTC thermistor 100 may include a positive end and a negative end.

The pull-up resistor unit 200, the DC power source 500, the protection resistor Rprotect, the voltage output unit 300, and the comparison unit 400, which will be described below, may be installed in an inverter 20.

The pull-up resistor unit 200 is connected to one end of the NTC thermistor 100, and its resistance changes depending on the temperature sensed inside the motor.

As illustrated in FIG. 1, the pull-up resistor unit 200 includes a first pull-up resistor 210, a second pull-up resistor 220, and a switch 230.

One end of the first pull-up resistor 210 is connected to the NTC thermistor 100.

The second pull-up resistor 220 is connected to the first pull-up resistor 210 in parallel.

The switch 230 is connected to the second pull-up resistor 220 in series, and is turned on or off depending on a signal input to a gate terminal. When the switch 230 is turned on, the first pull-up resistor 210 and the second pull-up resistor 220 are connected to each other, and the overall resistance of the pull-up resistor unit 200 decreases. On the other hand, when the switch 230 is turned off, the second pull-up resistor 220 is not connected in parallel to and is disconnected from the first pull-up resistor 210, the overall resistance of the pull-up resistor unit 200 increases.

The DC power source 500 outputs a constant voltage. The DC power source 500 may be connected to the first pull-up resistor 210 included in the pull-up resistor unit 200, and may be connected to a non-inverting terminal (+) included in a first comparator 420, which will be described below.

One end of the protection resistor Rprotect is connected to the other end of the NTC thermistor 100, and the other end of the protection resistor Rprotect is grounded. The protection resistor Rprotect is connected to the NTC thermistor 100 in series to prevent a flow of a large current when the resistance of the NTC thermistor 100 is low.

Referring to FIG. 1, a voltage output from the DC power source 500 is distributed to the pull-up resistor unit 200, the NTC thermistor 100, and the protection resistor Rprotect, which are connected to each other.

The voltage output unit 300 outputs a voltage based on a change in resistance of the NTC thermistor 100 according to a change in temperature. An output value output from the voltage output unit 300 may be the sum of voltages applied to the NTC thermistor 100 and the protection resistor Rprotect, which are connected to each other in series. That is, the voltage output unit 300 may be configured to include a voltage sensor.

The comparison unit 400 includes a comparator that compares a voltage value output from the voltage output unit 300 with a reference voltage, and changes a resistance of the pull-up resistor unit 200 according to an output of the comparator.

More specifically, referring to FIG. 1, the comparison unit 400 includes a first reference voltage output unit 410, a first comparator 420, a second reference voltage output unit 430, and a second comparator 440.

The first reference voltage output unit 410 outputs a 1-1st reference voltage or a 1-2nd reference voltage, and the second reference voltage output unit 430 outputs a second reference voltage.

The 1-1st reference voltage or the 1-2nd reference voltage output from the first reference voltage output unit 410 is input to a non-inverting terminal (+) of the first comparator 420, and the second reference voltage output from the second reference voltage output unit 430 is input to a non-inverting terminal (+) of the second comparator 440.

The 1-1st reference voltage output from the first reference voltage output unit 410 may be lower than the 1-2nd reference voltage.

The first reference voltage output unit 410 outputs the 1-1st reference voltage or the 1-2nd reference voltage according to an output of the first comparator 420. Specifically, the first reference voltage output unit 410 outputs the 1-1st reference voltage when the output of the first comparator 420 is “Low”, and outputs the 1-2nd reference voltage when the output of the first comparator 420 is “High”. At this time, the 1-1st reference voltage may be lower than the 1-2nd reference voltage. The specific process of outputting the 1-1st reference voltage and the 1-2nd reference voltage will be described below.

An inverting terminal (−) of the first comparator 420 is connected to one end of the NTC thermistor 100 and an output terminal of the voltage output unit 300.

The first comparator 420 compares the first reference voltage input to the non-inverting terminal (+) with the output value of the voltage output unit 300 input to the inverting terminal (−), and outputs “Low” or “High” depending on the comparison result.

More specifically, when switching from a low temperature section to a high temperature section, the resistance value of the NTC thermistor 100 decreases, and accordingly, the output of the voltage output unit 300 decreases. At this time, the output of the first comparator 420 is kept as “Low” due to the previous temperature condition. As a result, the first reference voltage output unit 410 outputs the 1-1st reference voltage. The first comparator 420 compares a voltage output from the voltage output unit 300 with the 1-1st reference voltage output from the first reference voltage output unit 410, and the first comparator 420 outputs “High” when the voltage output from the voltage output unit 300 is lower than the 1-1st reference voltage.

On the other hand, when switching from a high temperature section to a low temperature section, the resistance value of the NTC thermistor 100 increases, and accordingly, the output of the voltage output unit 300 increases. At this time, the output of the first comparator 420 is kept as “High” due to the previous temperature condition. As a result, the first reference voltage output unit 410 outputs the 1-2nd reference voltage. The first comparator 420 compares a voltage output from the voltage output unit 300 with the 1-2nd reference voltage output from the first reference voltage output unit 410, and the first comparator 420 outputs “Low” when the voltage of the voltage output unit 300 is higher than the 1-2nd reference voltage.

Generally, there is a difference of 5 V between “Low” and “High” output from the first comparator 420, and it is assumed that “Low” refers to 0 V and “High” refers to 5 V. In addition, the “Low” voltage output from the first comparator 420 may be equal to the ground voltage, and the “High” voltage may be equal to a voltage of the DC power source 500.

The second comparator 440 has a non-inverting terminal (+) connected to an output terminal of the second reference voltage output unit 430, and an inverting terminal (−) connected to an output terminal of the first comparator 420, to compare the second reference voltage and the output of first comparator 420. When the output value of the first comparator 420 is called Vout and the second reference voltage is Vref2, the second comparator 440 outputs “Low” when Vout is higher than Vref2, and outputs “High” when Vout is lower than Vref2. An output terminal of the second comparator 440 may be connected to the switch 230 described above. When the output of the second comparator 440 is “High”, the switch 230 is turned off and the resistance value of the pull-up resistor unit 200 increases, and when the output of the second comparator 440 is “Low”, the switch 230 is turned on and the resistance value of the pull-up resistor unit 200 decreases. This change in the resistance value of the pull-up resistor unit 200 ensures the linearity of the NTC thermistor 100 even at low and high temperatures, which is advantageous in that it is possible to achieve a temperature sensing device with high accuracy over a wide temperature range. In addition, in the present invention, the process of changing the resistance value of the pull-up resistor unit 200 is implemented through two comparators without separately designing software, which is advantageous in that it is possible to achieve a temperature sensing device having a relatively simple structure.

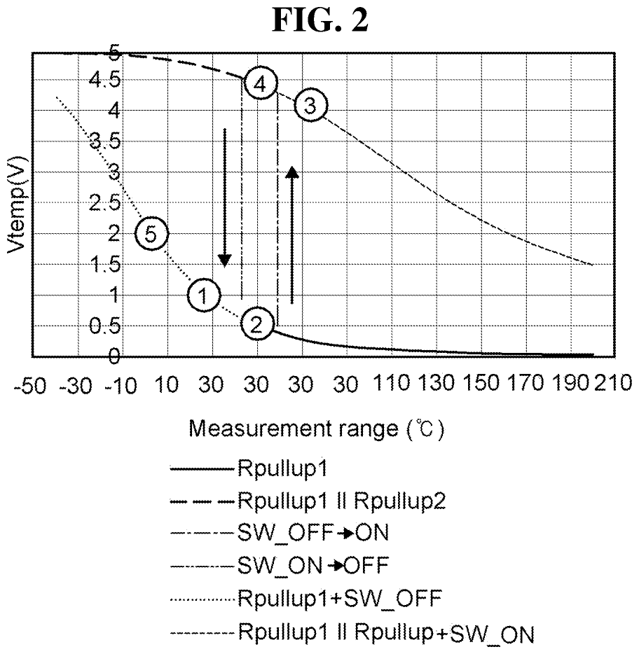

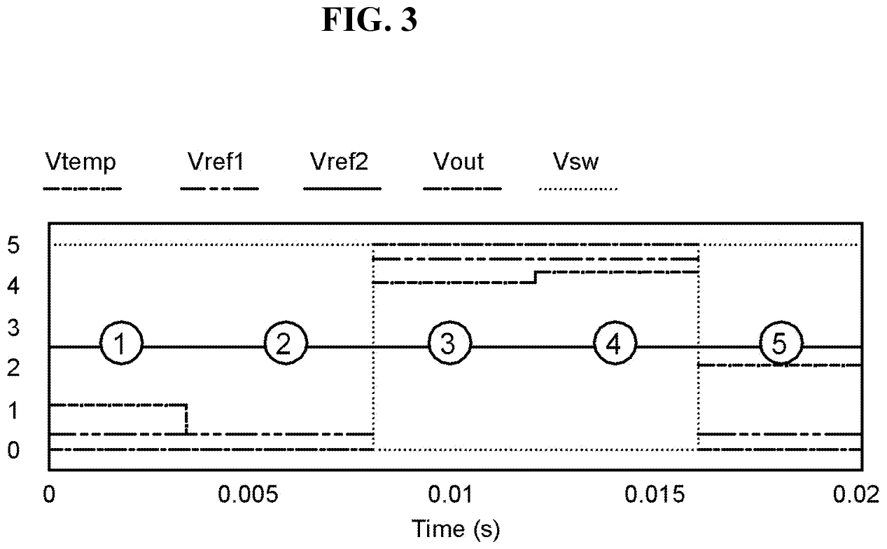

FIG. 2 is a graph showing a temperature measured by an NTC thermistor and a sensing signal voltage value Vtemp according to a change in resistance value of a pull-up resistor unit in the temperature sensing device according to an embodiment of the present invention, and FIG. 3 is a graph showing an output value of the voltage output unit 300, an output value of the first comparator 420, a signal value applied to the switch 230, a first reference voltage, and a second reference voltage in the temperature sensing device according to an embodiment of the present invention.

In FIGS. 2 and 3, No. 1 indicates a turn-off state of the switch 230, and Nos. 2 and 3 indicate a transition from a turn-off state to a turn-on state of the switch 230. In a state where the switch 230 is turned off, the resistance value of the pull-up resistor unit 200 increases because it is determined only by a first pull-up resistor Rpullup1, and accordingly, the voltage value of the sensing signal decreases according to the voltage distribution between the NTC thermistor 100 and the pull-up resistor unit 200 connected to each other in series. Therefore, it can be confirmed that the linearity of the NTC thermistor 100 is secured in a relatively low temperature region. On the other hand, in a state where the switch 230 is turned on, the resistance value of the pull-up resistor unit 200 decreases as compared with that in a state where the switch 230 is turned off because it is determined by the sum of a first pull-up resistor Rpullup1 and a second pull-up resistor Rpullup2 connected to each other in parallel, and accordingly, the voltage value of the sensing signal increases according to the voltage distribution between the NTC thermistor 100 and the pull-up resistor unit 200 connected to each other in series. Therefore, it can be confirmed that the linearity of the NTC thermistor 100 is secured in a relatively high temperature region. In FIG. 3, Vref1, which is a first reference voltage in Section Nos. 1, 2, and 5, may be a value of Vref1-1, which is a 1-1st reference voltage, and Vref1, which is a first reference voltage in Section Nos. 3 and 4, may be a value of Vref1-2, which is a 1-2nd reference voltage.

As illustrated in FIG. 1, the comparison unit 400 may include a first resistor R₁, a second resistor R₂, a third resistor R₃, and a fourth resistor R₄.

One end of the first resistor R₁ is connected to the non-inverting terminal (+) of the first comparator 420, and the other end of the first resistor R₁ is connected to the DC power source 500.

One end of the second resistor R₂ is connected to one end of the first resistor R₁, and the other end of the second resistor R₂ is connected to the inverting terminal (−) of the second comparator 440.

One end of the third resistor R₃ is connected to one end of the first resistor R₁, and the other end of the third resistor R₃ is grounded.

One end of the fourth resistor R₄ is connected to the other end of the first resistor R₁, and the other end of the fourth resistor R₄ is connected to the other end of the second resistor R₂.

Vref1-1, which is a 1-1st reference voltage used in the present invention, may be lower than Vref1-2, which is a 1-2nd reference voltage. For example, Vref1-1 may be 0.5 V, and Vref1-2 may be 4.5 V. However, the first reference voltage and the second reference voltage are not determined arbitrarily, but can be determined by the formulas below.

$${V}_{ref 1 - 1} = \frac{( {R}_{2} ‖ {R}_{3} )}{( {R}_{1} + {R}_{2} ‖ {R}_{3} )} \times {V}_{source}$$

(V_{ref1-1} is the 1-1st reference voltage, V_{source} is an output voltage of the DC power source 500, R₁ is a resistance value of the first resistor, R₂ is a resistance value of the second resistor, R₃ is a resistance value of the third resistor, and R₂∥R₃=(R₂·R₃)/(R₂+R₃).)

$${V}_{ref 1 - 2} = \frac{{R}_{3}}{( {R}_{1} ‖ {R}_{2} + {R}_{3} )} \times {V}_{source}$$

(V_{ref1-2} is the 1-2nd reference voltage, V_{source} is an output voltage of the DC power source 500, R₁ is a resistance value of the first resistor, R₂ is a resistance value of the second resistor, R₃ is a resistance value of the third resistor, and R₁∥R₂=(R₁·R₂)/(R₁+R₂).)

The 1-1st reference voltage and the 1-2nd reference voltage have formulas different from each other as described above, while the 1-1st reference voltage and the 1-2nd reference voltage vary as the voltage on the other end side of the second resistor R₂ changes according to the output of the first comparator 420.

Specifically, when the output of the first comparator 420 is “Low”, the second resistor R₂ forms a circuit connected to the third resistor R₃ in parallel, as shown in the above formula for calculating the 1-1st reference voltage. On the other hand, when the output of the first comparator 420 is “High”, the second resistor R₂ forms a circuit connected to the first resistor R₁ in parallel, as shown in the above formula for calculating the 1-2nd reference voltage.

At this time, it is preferable that the output voltage when the output of the first comparator 420 is “Low” has the same value as the ground voltage. In addition, it is preferable that the output voltage when the output of the first comparator 420 is “High” has the same value as the voltage of the DC power source 500.

Vref2, which is a second reference voltage, is simply a value for inverting Vout, which is an output of the first comparator 420, and may be determined as a value between 0 and 5 V, for example, 2.5 V. This is to output an output of the second comparator 440 differently from each output value of Vout, which is an output of the first comparator 420, because Vout appears in two cases: 0 V when the output is “Low” or 5 V when the output is “High”.

Although the preferred embodiments of the present invention have been described above, the embodiments disclosed herein are not intended to limit the technical idea of the present invention, but are provided to explain the technical idea of the present invention. Therefore, the technical idea of the present invention includes not only each of the embodiments disclosed herein but also a combination of the embodiments disclosed here, and furthermore, the scope of the technical idea of the present invention is not limited by these embodiments. In addition, those skilled in the art to which the present invention pertains may make numerous changes and modifications to the present invention without departing from the spirit and scope of the appended claims, and all of such appropriate changes and modifications shall be regarded as falling within the scope of the present invention as equivalents.

What is claimed is:

1. A temperature sensing device, comprising:
a negative temperature coefficient (NTC) thermistor installed on a motor;
a pull-up resistor connected to one end of the NTC thermistor, the pull-up resistor having a resistance that varies depending on a temperature inside the motor;
a voltage output unit configured to output a voltage based on a change in resistance of the NTC thermistor according to a change in temperature; and
a comparison unit including a comparator for comparing the voltage value output from the voltage output unit with a reference voltage,
wherein the comparison unit is configured to change the resistance of the pull-up resistor unit based on an output of the comparator.

2. The temperature sensing device of claim 1,
wherein the comparison unit includes:
a first reference voltage output unit for outputting a 1-1st reference voltage or a 1-2nd reference voltage; and
a second reference voltage output unit for outputting a second reference voltage, and
wherein the comparator includes:
a first comparator including:
a non-inverting terminal connected to an output terminal of the first reference voltage output unit; and
a first inverting terminal connected to one end of the NTC thermistor and the output terminal of the voltage output unit to compare the output voltage of the first reference voltage output unit with the output voltage of the voltage output unit; and
a second comparator including:
a non-inverting terminal being connected to an output terminal of the second reference voltage output unit; and
a second inverting terminal connected to an output terminal of the first comparator to compare the second reference voltage and the output of the first comparator, and turn on or off a switch included in the pull-up resistor unit according to an output.

3. The temperature sensing device of claim 2,
wherein, in response to the output of the first comparator being lower than a predetermined value based on the comparison result, the first reference voltage output unit outputs the 1-1st reference voltage, and
wherein, in response to the output of the first comparator being higher than the predetermined value based on the comparison result, the first reference voltage output unit outputs the 1-2nd reference voltage.

4. The temperature sensing device of claim 2, wherein the 1-1st reference voltage is lower than the 1-2nd reference voltage.

5. The temperature sensing device of claim 2, further comprising:
a direct current (DC) power source connected to the pull-up resistor unit and the comparison unit.

6. The temperature sensing device of claim 5, wherein the comparison unit further includes:
a first resistor of which one end is connected to the non-inverting terminal of the first comparator, and another end is connected to the DC power source;
a second resistor of which one end is connected to the one end of the first resistor, and another end is connected to the inverting terminal of the second comparator;
a third resistor of which one end is connected to the one end of the first resistor, and another end is grounded; and
a fourth resistor of which one end is connected to the other end of the first resistor, and another end is connected to the other end of the second resistor.

7. The temperature sensing device of claim 6, wherein the 1-1st reference voltage is determined by the following formula:
$${V}_{ref 1 - 1} = \frac{( {R}_{2} ‖ {R}_{3} )}{( {R}_{1} + {R}_{2} ‖ {R}_{3} )} \times {V}_{source}$$
where V_{ref1-1} is the 1-1st reference voltage, V_{source} is an output voltage of the DC power source, R₁ is a resistance value of the first resistor, R₂ is a resistance value of the second resistor, R₃ is a resistance value of the third resistor, and R₂∥R₃=(R₂·R₃)/(R₂+R₃).

8. The temperature sensing device of claim 6, wherein the 1-2nd reference voltage is determined by the following formula:
$${V}_{ref 1 - 2} = \frac{{R}_{3}}{( {R}_{1} ‖ {R}_{2} + {R}_{3} )} \times {V}_{source}$$
where V_{ref1-2} is the 1-2nd reference voltage, V_{source} is an output voltage of the DC power source, R₁ is a resistance value of the first resistor, R₂ is a resistance value of the second resistor, R₃ is a resistance value of the third resistor, and R₁∥R₂=(R₁·R₂)/(R₁+R₂).

9. The temperature sensing device of claim 2, wherein the pull-up resistor unit includes:
a first pull-up resistor of which one end is connected to the NTC thermistor;
a second pull-up resistor connected to the first pull-up resistor in parallel; and
a switch connected to the second pull-up resistor in series, with a gate terminal thereof being connected to an output terminal of the second comparator, the gate terminal configured to turn on or off the switch according to an output of the second comparator.

10. The temperature sensing device of claim 1, further comprising:
a protection resistor of which one end is connected to the other end of the NTC thermistor, and another end is grounded.

11. A temperature sensing device for a vehicle, the device comprising:
a negative temperature coefficient (NTC) thermistor installed on a motor of the vehicle;
a pull-up resistor connected to the NTC thermistor, the pull-up resistor having a resistance that varies depending on a temperature of the motor;
a voltage outputter configured to output a voltage based on a change in resistance of the NTC thermistor due to a change of the temperature of the motor; and
a controller comprising a comparator for comparing the voltage value output by the voltage outputter with a reference voltage,
wherein the controller is configured to change the resistance of the pull-up resistor unit based on the comparison of the voltage value output by the voltage outputter with the reference voltage by the comparator.

12. The device of claim 11,
wherein the controller includes:
a first reference voltage outputter for outputting a 1-1st reference voltage or a 1-2nd reference voltage; and
a second reference voltage outputter for outputting a second reference voltage, and
wherein the comparator includes:
a first comparator including:
a non-inverting terminal connected to an output terminal of the first reference voltage outputter; and
a first inverting terminal connected to one end of the NTC thermistor and the output terminal of the voltage outputter to compare the output voltage of the first reference voltage outputter with the output voltage of the voltage outputter; and
a second comparator including:
a non-inverting terminal being connected to an output terminal of the second reference voltage outputter; and
a second inverting terminal connected to an output terminal of the first comparator to compare the second reference voltage and the output of the first comparator, and turn on or off a switch included in the pull-up resistor according to an output.

13. The device of claim 12,
wherein, in response to the output of the first comparator being lower than a predetermined value based on the comparison result, the first reference voltage outputter outputs the 1-1st reference voltage, and
wherein, in response to the output of the first comparator being higher than the predetermined value based on the comparison result, the first reference voltage outputter outputs the 1-2nd reference voltage.

14. The device of claim 12, wherein the 1-1st reference voltage is lower than the 1-2nd reference voltage.

15. The device of claim 12, further comprising:
a direct current (DC) power source connected to the pull-up resistor and the controller.
